(19) United States
(12) Patent Application Publication
(10) Pub. No.: US 2012/0172232 A1
(43) Pub. Date: Jul. 5, 2012

(54) Nanorod-containing precursor powder, nanorod-containing superconductor bulk and method for manufacturing the same

(75) Inventors: In-Gann Chen, Tainan City (TW); Chun-Chih Wang, Tainan City (TW); Shih-Hsun Huang, Tainan City (TW)

(73) Assignee: National Cheng Kung University, Tainan City (TW)

(21) Appl. No.: 13/067,901

(22) Filed: Jul. 6, 2011

(30) Foreign Application Priority Data
Jan. 5, 2011 (TW) 100100369

(51) Int. Cl. H01L 39/12; H01B 1/08; C23C 16/00; H01L 39/24; C30B 19/00; B82Y 40/00; B82Y 30/00

(52) U.S. Cl. 505/126; 427/255.28; 252/519.5; 505/300; 505/100; 977/890; 977/762; 117/54

(57) ABSTRACT

The present invention relates to a nanorod-containing precursor powder, a nanorod-containing superconductor bulk and a method for manufacturing the same. The method for manufacturing a nanorod-containing precursor powder includes the following steps: providing a precursor powder; and forming a plurality of nanorods on particle surfaces of the precursor powder. Accordingly, the present invention can significantly enhance critical current density and pinning force.

### CROSS REFERENCE TO RELATED APPLICATION

This application claims the benefits of the Taiwan Patent Application Serial Number 100100369, filed on Jan. 5, 2011, the subject matter of which is incorporated herein by reference.

### BACKGROUND OF THE INVENTION

1. Field of the Invention

The present invention relates to a nanorod-containing precursor powder, a nanorod-containing superconductor bulk and a method for manufacturing the same, more particularly, to a nanorod-containing precursor powder advantageous to the enhancement of critical current density and magnetic trapping field, a nanorod-containing superconductor bulk and a method for manufacturing the same.

2. Description of Related Art

Superconductors can be significantly distinguished from other materials by their two characteristic properties, zero resistance and diamagnetism. Y₁Ba₂Cu₃O₇₋ₓ is the first discovered superconductor with a critical temperature greater than the boiling point (i.e. 77K) of liquid nitrogen and thus is called high-temperature superconductor. The discovery of high-temperature superconductors is advantageous to the reduction of cost required for cooling and the application of superconductors in practical industry.

Superconductors can be widely applied. For instance, superconductor bulk can be applied in bearing or clear magnet, owing to their high flux trapping ability or magnetic suspension effect. The practical applications of superconductors include, for example, magnetic suspension bearings, magnetic suspension transport systems, high efficiency motors, generators, medical diagnostic equipments, microwave communication, high-speed computers, energy storage and conversion etc.

Presently, the top-seeded melt-textured growth has been the main method for growing single grain of high-temperature superconductor, in which REBa₂Cu₃O₇ and REBa₂CuO₅ would be mixed in an appropriate ratio and then larger single grain of REBa₂Cu₃O₇ can be grown by peritectic reaction. The bulk manufactured by this method can exhibit excellent critical current density under low magnetic field (less than 2 T at 77K). However, its critical current density would be seriously decayed due to the increase of magnetic field, and thus the bulk is unfavorable to applications under high magnetic field, resulting in the restriction on its application.

The bulks of high-temperature superconductors require high critical current density (Jc) to perform high magnetic trapping field for practical applications. Accordingly, the pinning center doping in superconductors was reported to contribute to the enhancement of critical current density and magnetic trapping field. Taking Y—Ba—Cu—O as an example, additives such as Pt and CeO₂ were suggested to be added in the melt growth process. However, this method mainly enhances critical current density under low magnetic field. In addition, adding trace dopants for breaking lattice of superconductors and thus inducing weak superconductivity phase was reported to enhance critical current density under high magnetic field, in which the weak superconductivity phase can function as pinning center under high magnetic field and thereby enhance the critical current density. As prior art, zero-dimension dopants in powder form were added to induce zero-dimension pinning centers. However, the zero-dimension pinning centers are not the most efficient ones for one-dimension magnetic lines. Thereby, it is desired to induce pinning centers in one-dimension as magnetic lines into superconductor bulks to enhance their critical current density and magnetic trapping field.

### SUMMARY OF THE INVENTION

The object of the present invention is to provide a nanorod-containing precursor powder and a method for manufacturing the same, which can enhance critical current density and magnetic trapping field of superconductor bulks even at high magnetic field. In addition, the manufacturing method provided by the present invention has advantages of simple process, no impurity, low danger, low cost and no agglomeration, and can be applied in bulks without limitation in dimension.

To achieve the object, the present invention provides a method for manufacturing nanorod-containing precursor powder, including: (A) providing a precursor powder; and (B) forming a plurality of nanorods on particle surfaces of the precursor powder.

Accordingly, the present invention directly grows a plurality of nanorods on the precursor powder as pinning centers of the superconductor bulk. Compared to the method of growing columnar defects and then mixing the columnar defects with precursor powder, the present invention directly grows nanorods on particle surfaces of the precursor powder, and thereby can inhibit agglomeration of nanorods and avoid non-uniform mixing. Additionally, Compared to the method of growing columnar defects on a substrate or the hydrothermal method for forming columnar defects, the method provided by the present invention can avoid the generation of impurity and thus can prevent impurity from affecting the superconducting properties of the bulk.

In the method for manufacturing precursor powder according to the present invention, the precursor powder may be any precursor powder for the preparation of a superconductor bulk, and is not particularly limited. For instance, the precursor powder can include Y₂BaCuO₅ (Y211) powder, Y₁Ba₂Cu₃O₇₋ₓ (0≦x≦0.5) (Y123) powder, additional dopants or a mixture thereof.

In the method for manufacturing precursor powder according to the present invention, the nanorods are not particularly limited, and may be any nanorods that can induce the formation of weak superconductivity phase. For instance, the nanorods may be made of a rare earth metal, a group 1A metal, a group 3d metal, a rare earth metal compound, a group 1A metal compound or a group 3d metal compound. Preferably, the nanorods are zinc oxide nanorods, nickel oxide nanorods or a mixture thereof.

In the method for manufacturing precursor powder according to the present invention, the method for forming the nanorods is not particularly limited, and can be any method for forming nanorods on precursor powder. For instance, a chemical vapor deposition process may be selected to form nanorods. Accordingly, in the present invention, a reactive vapor can be further provided in the step (A), and a chemical vapor deposition process can be performed in the step (B) to react the reactive vapor into nanorods on particle surfaces of the precursor powder. In the case of forming nanorods by chemical vapor deposition, the reactive vapor is not particularly limited, and can be any vapor that contains at least one reactive metal element and can react to form nanorods by chemical vapor deposition. The reactive metal element preferably is one that can replace Cu²⁺ in the lattice face through which superconducting current passes, such as zinc and nickel. In addition, the reactive vapor may be, for example, a metal vapor (e.g. zinc vapor, nickel vapor or a mixed vapor of zinc and nickel), and can be formed by heating metal powder (e.g. zinc powder, nickel powder or a mixture thereof) to a predetermined temperature. Accordingly, the metal vapor can react with the input reactive gas (e.g. oxygen) to form a plurality of nanorods (e.g. zinc oxide nanorods, nickel oxide nanorods or a mixture thereof) on particle surfaces of the precursor powder. Herein, the input concentration of the reactive gas may be about 10⁴ ppm-10⁶ ppm. In detail, the reactive gas can be input when the metal vapor reaches its saturation vapor pressure at a predetermined temperature (e.g. 500° C.), and the input concentration of the reactive gas preferably is 0.5×10⁵ ppm-2×10⁵ ppm. Alternatively, the reactive gas can be input when the metal vapor is accumulated for about 15 minutes to 30 minutes at a predetermined temperature (e.g. 500° C.), and the input concentration of the reactive gas preferably is 1.0×10⁵ ppm. Besides, a cooling process may be performed when inputting the reactive gas so as to react the reactive gas with the metal vapor to form nanorods on particle surfaces of the precursor powder.

In the method for manufacturing precursor powder according to the present invention, the nanorods preferably are about 10 or more (more preferably 15-20) in aspect ratio, about 20 nm-1000 nm (more preferably 35 nm-50 nm) in diameter and about 1 μm-2 μm in length.

In the method for manufacturing precursor powder according to the present invention, the nanorods in the precursor powder are not particularly limited in amount. For instance, based on the weight of the precursor powder, the nanorods contained in the precursor powder may be about 2-5 wt % in terms of metal elements of the nanorods.

Accordingly, the present invention further provides a nanorod-containing precursor powder, including: a precursor powder; and a plurality of nanorods formed on particle surfaces of the precursor powder.

In the nanorod-containing precursor powder according to the present invention, the precursor powder may be any precursor powder for the preparation of a superconductor bulk, and is not particularly limited. For instance, the precursor powder can include Y₂BaCuO₅ (Y211) powder, Y₁Ba₂Cu₃O₇₋ₓ (0≦x≦0.5) (Y123) powder, additional dopants or a mixture thereof.

In the nanorod-containing precursor powder according to the present invention, the nanorods are not particularly limited, and may be any nanorods that can induce the formation of weak superconductivity phase. For instance, the nanorods may be made of a rare earth metal, a group 1A metal, a group 3d metal, a rare earth metal compound, a group 1A metal compound or a group 3d metal compound. Preferably, the nanorods are zinc oxide nanorods, nickel oxide nanorods or a mixture thereof.

In the nanorod-containing precursor powder according to the present invention, the nanorods preferably are about 10 or more (more preferably 15-20) in aspect ratio, about 20 nm-1000 nm (more preferably 35 nm-50 nm) in diameter and about 1 μm-2 μm in length.

In the nanorod-containing precursor powder according to the present invention, the nanorods in the precursor powder are not particularly limited in amount. For instance, based on the weight of the precursor powder, the nanorods contained in the precursor powder may be about 2-5 wt % in terms of metal elements of the nanorods.

According to the present invention, the nanorod-containing precursor powder can be further used for the preparation of a superconductor bulk with enhanced critical current density and magnetic trapping field.

Accordingly, the present invention further provides a method for manufacturing a nanorod-containing superconductor bulk, including: (A) providing a first nanorod-containing precursor powder and forming the first nanorod-containing precursor powder into an embryo, in which the first nanorod-containing precursor powder includes a first precursor powder and a plurality of nanorods formed on particle surfaces of the first precursor powder; and (B) performing a melt growth process to prepare a superconductor bulk.

According to the method for manufacturing a superconductor bulk of the present invention, in the step (A), a second precursor powder can be further provided, and the second precursor powder can be mixed with the first nanorod-containing precursor powder to prepare the embryo.

According to the method for manufacturing a superconductor bulk of the present invention, the first precursor powder and the second precursor powder may be any precursor powder for the preparation of a superconductor bulk, and are not particularly limited. For instance, the first precursor powder and the second precursor powder can individually include Y₂BaCuO₅ (Y211) powder, Y₁Ba₂Cu₃O₇₋ₓ (0≦x≦0.5) (Y123) powder, additional dopants or a mixture thereof.

According to the method for manufacturing a superconductor bulk of the present invention, the nanorods are not particularly limited, and may be any nanorods that can induce the formation of weak superconductivity phase. For instance, the nanorods may be made of a rare earth metal, a group 1A metal, a group 3d metal, a rare earth metal compound, a group 1A metal compound or a group 3d metal compound. Preferably, the nanorods are zinc oxide nanorods, nickel oxide nanorods or a mixture thereof.

According to the method for manufacturing a superconductor bulk of the present invention, the melt growth process preferably is a top-seeded melt-textured growth process. In detail, preferably, a single crystal seed (e.g. SmBCO, NdBCO, MgO) with a certain orientation is first placed on an embryo and then a melt growth process is performed, in which the growth and nucleation of a bulk is controlled in a melt state by a seeding manner. Herein, those having ordinary knowledge in the art can modify the process parameters according to the desired grain size.

According to the method for manufacturing a superconductor bulk of the present invention, the nanorods preferably are about 10 or more (more preferably 15-20) in aspect ratio, about 20 nm-1000 nm (more preferably 35 nm-50 nm) in diameter and about 1 g m-2 μm in length.

According to the method for manufacturing a superconductor bulk of the present invention, the nanorods in the first precursor powder are not particularly limited in amount. For instance, based on the weight of the first precursor powder, the nanorods contained in the first precursor powder may be about 2-5 wt % in terms of metal elements of the nanorods.

According to the method for manufacturing a superconductor bulk of the present invention, the nanorods in the embryo are not particularly limited in amount. For instance, the nanorods contained in the embryo may be about 0.01-0.1 wt % based on the total weight of the embryo.

Accordingly, the present invention further provides a nanorod-containing superconductor bulk, including a single-domain bulk; and a plurality of nanorods dispersed in the single-domain bulk.

In the nanorod-containing superconductor bulk according to the present invention, the single-domain bulk is not particularly limited, and may be, for example, an YBCO single-domain bulk. More specifically, the YBCO single-domain bulk can include an Y₁Ba₂Cu₃O₇₋ₓ (0≦x≦0.5) phase. Preferably, the YBCO single-domain bulk further includes a plurality of Y₂BaCuO₅ particles dispersed in the Y₁Ba₂Cu₃O₇₋ₓ phase.

In the nanorod-containing superconductor bulk according to the present invention, the nanorods are not particularly limited, and may be any nanorods that can induce the formation of weak superconductivity phase. For instance, the nanorods may be made of a rare earth metal, a group 1A metal, a group 3d metal, a rare earth metal compound, a group 1A metal compound or a group 3d metal compound. Preferably, the nanorods are zinc oxide nanorods, nickel oxide nanorods or a mixture thereof.

In the nanorod-containing superconductor bulk according to the present invention, the nanorods are not particularly limited in amount. For instance, the nanorods contained in the superconductor bulk may be about 0.01-0.1 wt % based on the total weight of the superconductor bulk, in which the metal elements on the surfaces of nanorods can partly replace the elements in the single-domain bulk to form weak superconductivity phase, such as Y₁Ba₂(Cu_{1-y}M_{y})₃O₇₋ₓ (0≦x≦0.5, 0<y≦0.5, and M is metal elements contained in nanorods). Accordingly, taking zinc oxide nanorods and nickel oxide nanorods for exemplary illustration, the surfaces of the zinc oxide nanorods and nickel oxide nanorods can be formed into Y₁Ba₂(Cu_{1-y}Zn_{y})₃O₇₋ₓ (0≦x≦0.5, 0<y≦0.5) phase and Y₁Ba₂(Cu_{1-y}Ni_{y})₃O₇₋ₓ (0≦x≦0.5, 0<y≦0.5) phase, respectively.

In the nanorod-containing superconductor bulk according to the present invention, the nanorods preferably are about 10 or more (more preferably 15-20) in aspect ratio, about 20 nm-1000 nm (more preferably 35 nm-50 nm) in diameter and about 1 μm-2 μm in length.

Accordingly, the present invention directly grows a plurality of nanorods on the precursor powder as pinning centers of the superconductor bulk. Compared to the method of growing columnar defects and then mixing the columnar defects with precursor powder, the present invention directly grows nanorods on particle surfaces of the precursor powder, and thereby can inhibit agglomeration of nanorods and avoid non-uniform mixing. Additionally, Compared to the method of growing columnar defects on a substrate or the hydrothermal method for forming columnar defects, the method provided by the present invention can avoid the generation of impurity and thus can prevent impurity from affecting the superconducting properties of the bulk.

### BRIEF DESCRIPTION OF THE DRAWINGS

FIG. 1 shows a temperature curve with regard to a top-seeded melt-textured growth process according to a preferred example of the present invention; and

FIG. 2 shows a critical current density vs. field strength diagram according to Examples 2-1 to 2-3, Comparative Example 1-1, Comparative Examples 2-1 to 2-3 and Comparative Examples 3-1 to 3-3.

### DETAILED DESCRIPTION OF THE PREFERRED EMBODIMENT

Hereafter, examples will be provided to illustrate the embodiments of the present invention. Various modifications and variations can be made without departing from the spirit of the invention based on various concepts and applications. The following examples are provided for illustration purposes, but are not to be construed to limit claims of the present invention.

### Example 1

### Preparation of Nanorod-Containing Precursor Powder

Carbon powder of 0.05 g and zinc powder of 0.05 g were mixed and placed into a tube. Additionally, a precursor powder (the present example used Y₂BaCuO₅ (Y211) for exemplary illustration, but usable precursor powder is not limited to Y211 illustrated by the present example) was spread on a silicon substrate cleaned by RCA, and then the silicon substrate was placed into the tube. Subsequently, the tube was disposed on a quartz carrier and placed at the canter within a tube furnace, and then a chemical vapor deposition process was performed in an open system. The temperature was raised to 500° C. at 400° C./hr (the temperature drop between the center of the furnace to the location apart forth and back from the center about 5 cm being 1° C.) and maintained for 30 minutes (i.e. the accumulation time of zinc vapor T_{holde} being 30 minutes), followed by cooling and then inputting a gas mixture at a total flux of 200 sccm containing a carrier gas (N₂) at 180 sccm and a reactive gas (O₂) at 20 sccm (i.e. the concentration of the reactive gas being 10⁵ ppm) to growth ZnO nanorods on particle surfaces of the precursor powder. Then, the tube was taken out and the precursor powder adhered on the silicon substrate was shaken off and collected. Finally, the morphology of the collected precursor powder was observed by scanning electron microscopy (SEM). The precursor powder containing ZnO nanorods with the aspect ratio higher than 10 was collected, therewith the ZnO nanorods being about 50 nm in average diameter, about 1 μm in average length and about 15-20 in aspect ratio.

In addition, the collected precursor powder was dissolved in HCl and HClO₄ in sequence, and then be measured by an inductively coupled plasma mass spectrometer (ICP-MS, PE-SCIEX ELAN 6100 DRC). The result showed that the precursor powder contained zinc in an amount of about 2-5 wt %, based on the weight of the precursor powder.

The method for manufacturing nanorods illustrated by the above-mentioned example 1 is intended to be served as a preferable embodiment, and the process parameters with regard to the process for manufacturing nanorods are not limited to those illustrated by the above-mentioned example 1. Those skilled in the art can refer to the manufacturing scheme illustrated by the above-mentioned example 1 and modify each process parameter to fabricate nanorods. In detail, the accumulation time of zinc vapor (T_{hold}) may be altered to 18 minutes for example to manufacture ZnO nanorods with non-uniform length. Also, the concentration of the reactive gas may be modified. For example, in a closed system, the temperature can be raised to 500° C. and then maintained for 30 minutes to make the zinc vapor reach its saturation vapor pressure, followed by inputting the reactive gas O₂ in a concentration between 0.5×10⁵ ppm (i.e. the carrier gas N₂ being 190 sccm and the reactive gas O₂ being 10 sccm) and 2×10⁵ ppm (i.e. the carrier gas N₂ being 160 sccm and the reactive gas O₂ being 40 sccm), to manufacture ZnO nanorods. Accordingly, nanorods of about 100 nm-1000 nm in diameter, about 1 μm-2 μm in length and about 10 or more in aspect ratio can be grown on the precursor powder according to the manufacturing method provided by the present invention, therewith the zinc contained in the precursor powder being about 2-5 wt % based on the weight of the precursor powder.

### Example 2-1

### Preparation of a Bulk Containing ZnO Nanorods in 0.1 wt %

A first nanorod-containing precursor powder and a second nanorod-free precursor powder were provided in an appreciate amount, and then mixed thoroughly by an agate mortar. Herein, the present example used Y211 as the first precursor powder (containing nanorods) for exemplary illustration, and the usable first precursor powder is not limited to Y211 illustrated by the present example. In addition, the present example used a mixture of Y123 and Y211 precursor powders as the second precursor powder for exemplary illustration, and the usable second precursor powder is not limited to the mixture of Y123 and Y211 precursor powders illustrated by the present example. Herein, after mixing the first nanorod-containing precursor powder and the second nanorod-free precursor powder, the mixture can contain Y123 in an amount of about 75-85 wt % and Y211 (including pure Y211 and nanorod-containing Y211) in an amount of about 15-25 wt %, based on the total weight of the mixture. In the present example, 85 wt % of pure Y123 (about 21.25 g) and 15 wt % of pure Y211 (about 3.096 g) and nanorod-containing Y211 (about 0.654 g, the total surface area of ZnO being about 3.65×10¹⁷ nm²) were provided to obtain a mixture of precursor powders containing about 0.1 wt % of nanorods.

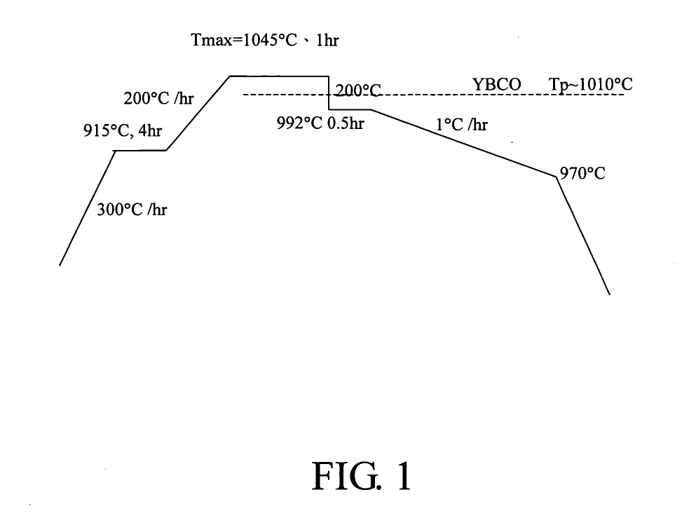

Subsequently, a pressure-forming process was performed by a uniaxial hydraulic press, in which the pressure was set as 25-35 kgf/cm². The obtained embryo was placed into a high temperature furnace in the presence of an SmBCO single crystal seed (001 orientation) to perform a top-seeded melt-textured growth process for the growth of a single grain. The temperature curve of this process is shown in FIG. 1.

In the top-seeded melt-textured growth process, Y123 and Y211 were used as starting materials. Y123 and Y211 powders were synthesized from Y₂O₃, BaCO₃ and CuO by a solid-state reaction, as shown in the following simplified chemical reaction:

Y₂O₃+4BaCO₃+6CuO→2YBa₂Cu₃O_{6.5}+4CO₂

Y₂O₃+BaCO₃+CuO→Y₂BaCuO₅+CO₂

Y₂O₃, BaCO₃ and CuO were provided in the above-mentioned atomic mole ratio and placed in an agate mortar, followed by adding 99.5% of anhydrous alcohol in an appropriate amount. After the starting materials were ground and uniformly mixed, the mixture of powders was placed into an aluminum oxide crucible, and maintained in a loose state to allow the diffusion of CO₂ generated during reaction. The obtained powder was sieved into 270 mesh powder for the preparation of the embryo.

### Example 2-2

### Preparation of a Bulk Containing ZnO Nanorods in 0.05 wt %

The preparation method according to the present example was similar to that illustrated in Example 2-1, except that the present example provided pure Y123 precursor powder in 21.25 g, pure Y211 precursor powder in 3.423 g and ZnO nanorod-containing Y211 precursor powder in 0.327 g (the total surface area of ZnO being 1.82×10¹⁷ nm²) to prepare a bulk containing ZnO nanorods in 0.05 wt %.

### Example 2-3

### Preparation of a Bulk Containing ZnO nanorods in 0.01 wt %

The preparation method according to the present example was similar to that illustrated in Example 2-1, except that the present example provided pure Y123 precursor powder in 21.25 g, pure Y211 precursor powder in 3.685 g and ZnO nanorod-containing Y211 precursor powder in 0.065 g (the total surface area of ZnO being 3.65×10¹⁶ nm²) to prepare a bulk containing ZnO nanorods in 0.01 wt %.

### Comparative Example 1-1

### Preparation of a ZnO-Free Bulk

The preparation method according to the comparative example was similar to that illustrated in Example 2-1, except that the comparative example provided pure Y123 precursor powder in 21.25 g and pure Y211 precursor powder in 3.75 g to prepare a ZnO-free bulk.

### Comparative Example 2-1

### Preparation of a Bulk Containing ZnO Nanoparticles in 0.1 wt %

The preparation method according to the comparative example was similar to that illustrated in Example 2-1, except that the comparative example provided pure Y123 precursor powder in 21.25 g, pure Y211 precursor powder in 3.75 g and ZnO nanoparticles (their average diameter being about 60 nm and their total surface area being 3.85×10¹⁷ nm²) in 0.025 g to prepare a bulk containing ZnO nanoparticles in 0.1 wt %.

### Comparative Example 2-2

### Preparation of a Bulk Containing ZnO Nanoparticles in 0.05 wt %

The preparation method according to the comparative example was similar to that illustrated in Example 2-1, except that the comparative example provided pure Y123 precursor powder in 21.25 g, pure Y211 precursor powder in 3.75 g and ZnO nanoparticles (their average diameter being about 60 nm and their total surface area being 1.92×10¹⁷ nm²) in 0.0125 g to prepare a bulk containing ZnO nanoparticles in 0.05 wt %.

### Comparative Example 2-3

### Preparation of a Bulk Containing ZnO Nanoparticles in 0.01 wt %

The preparation method according to the comparative example was similar to that illustrated in Example 2-1, except that the comparative example provided pure Y123 precursor powder in 21.25 g, pure Y211 precursor powder in 3.75 g and ZnO nanoparticles (their average diameter being about 60 nm and their total surface area being 0.385×10¹⁷ nm²) in 0.0025 g to prepare a bulk containing ZnO nanoparticles in 0.01 wt %.

### Comparative Example 3-1

### Preparation of a Bulk Containing ZnO Submicron Particles in 0.1 wt %

The preparation method according to the comparative example was similar to that illustrated in Example 2-1, except that the comparative example provided pure Y123 precursor powder in 21.25 g, pure Y211 precursor powder in 3.75 g and ZnO submicron particles (their average diameter being about 500 nm and their total surface area being 5.35×10¹⁶ nm²) in 0.025 g to prepare a bulk containing ZnO submicron particles in 0.1 wt %.

### Comparative Example 3-2

### Preparation of a Bulk Containing ZnO Submicron Particles in 0.05 wt %

The preparation method according to the comparative example was similar to that illustrated in Example 2-1, except that the comparative example provided pure Y123 precursor powder in 21.25 g, pure Y211 precursor powder in 3.75 g and ZnO submicron particles (their average diameter being about 500 nm and their total surface area being 2.67×10¹⁶ nm²) in 0.0125 g to prepare a bulk containing ZnO submicron particles in 0.05 wt %.

### Comparative Example 3-3

### Preparation of a Bulk Containing ZnO Submicron Particles in 0.01 wt %

The preparation method according to the comparative example was similar to that illustrated in Example 2-1, except that the comparative example provided pure Y123 precursor powder in 21.25 g, pure Y211 precursor powder in 3.75 g and ZnO submicron particles (their average diameter being about 500 nm and their total surface area being 5.35×10¹⁵ nm²) in 0.0025 g to prepare a bulk containing ZnO submicron particles in 0.01 wt %.

### [Test Example]

The critical temperature (T_{c}) and critical current density (J_{c}) of superconductor bulks prepared by Examples 2-1 to 2-3, Comparative Examples 1-1, 2-1 to 2-3 and 3-1 to 3-3 were measured by a superconducting quantum interference device (SQUID).

### A. Influence of ZnO Appearance on Critical Temperature

The specimen was zero-field cooled (ZFC) to 5K to measure the critical temperature (T_{c}) under an applied magnetic field of 10 Oe. The magnetic susceptibilities at different temperatures were measured until the temperature was raised to 120 K. The peak temperature determined from the first order derivative of magnetic susceptibility with respect to temperature is defined as the critical temperature (T_{c}), and the results are shown in the following table 1.

TABLE 1

| | T_{c} |
|---|---|
| Example 2-1 | 87.5 K |
| Example 2-2 | 88.3 K |
| Example 2-3 | 88.8 K |
| Comparative Example 1-1 | 90 K |
| Comparative Example 2-1 | 86.7 K |
| Comparative Example 2-2 | 87.9 K |
| Comparative Example 2-3 | 88.7 K |
| Comparative Example 3-1 | 88.2 K |
| Comparative Example 3-2 | 89.0 K |
| Comparative Example 3-3 | 89.7 K |

From Table 1, it can be found that the critical temperature would decrease with the concentration increase of ZnO dopants (i.e. ZnO nanorods, nanoparticles and submicron particles). Thereby, it can be confirmed that the increase of Zn replacement amount can cause T_{c} reduction. In addition, comparing the critical temperatures under the same doping concentration, it can be found that T_{c} of the bulk doped with submicron particles >T_{c} of the bulk doped with nanorods >T_{c} of the bulk doped with nanoparticles due to that the submicron particles have the smallest surface area and the nanorods have smaller surface area than the nanoparticles.

### B. Influence of ZnO Appearance on Critical Current Density

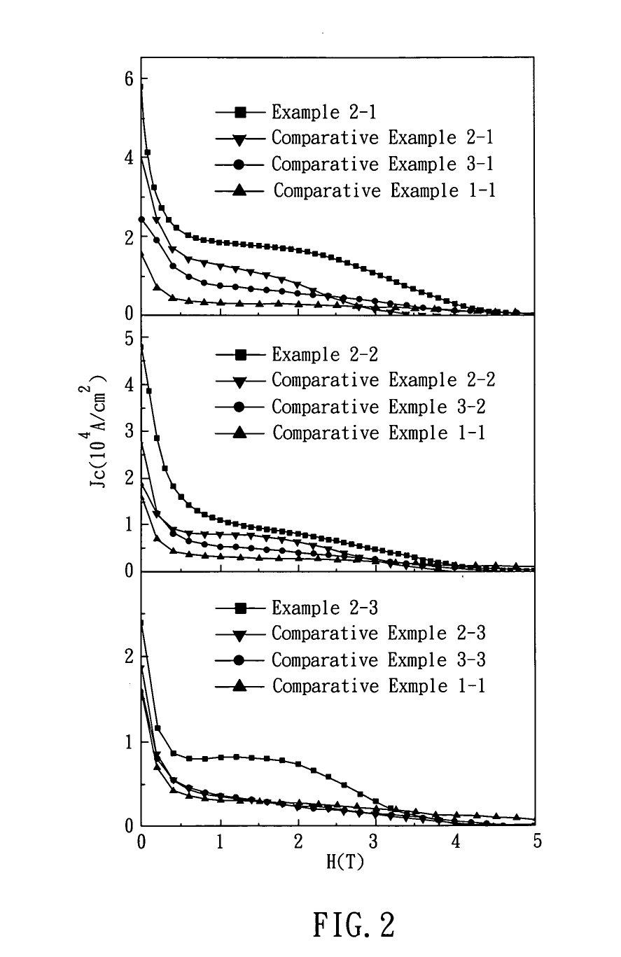

The critical current density J_{c} (A/cm²) was obtained by measuring the M-H curve and then calculating J_{c} from the equation, J_{c}=20 ΔM/[a(1−a/3b)], in which a and b are side lengths (cm) of the specimen (a>b) and ΔM means magnetic susceptibility (emu/cm³). FIG. 2 shows the measured critical current densities at 77 K at the exterior of the bulks prepared by Examples 2-1 to 2-3, Comparative Example 1-1, Comparative Examples 2-1 to 2-3 and Comparative Examples 3-1 to 3-3.

As shown in FIG. 2, with respect to the critical current density, the bulk doped with nanorods (i.e. Examples 2-1 to 2-3) is higher than that doped with nanoparticles (i.e. Comparative Examples 2-1 to 2-3), the bulk doped with nanoparticles is higher than that doped with submicron particles (i.e. Comparative Examples 3-1 to 2-3), and the standard (i.e. Comparative Example 1-1) is the lowest. Additionally, J_{c} values of the bulk doped with nanoparticles (i.e. Comparative Example 2-3) and the bulk doped with submicron particles (i.e. Comparative Example 3-3) are not significantly enhanced under low doping concentration compared to the standard (i.e. Comparative Example 1-1), and the increase tendency of J_{c} becomes more apparent with the increase of doping concentration. From the experimental results, it can be known that the critical current density of the bulk doped with nanorods is higher than that doped with nanoparticles under zero field and high field. Thereby, it can be confirmed that columnar defects can cause efficient enhancement, and more pinning centers can be formed by doping nanorods in higher concentration.

### C. Influence of ZnO Appearance on Pinning Force

The pinning force Fₚ can be calculated by the equation, Fₚ=J_{c}×H, in which J_{C}(H,T) and the applied field H can be obtained by the above-mentioned experiments, and Fₚₘₐₓ is the maximum among all obtained Fₚ values. The results are shown in the following table 2.

TABLE 2

| | Fpₘₐₓ(H) |
|---|---|
| Example 2-1 | 34.9 kT × A/cm² (2.4T) |
| Example 2-2 | 20.6 kT × A/cm² (2.4T) |
| Example 2-3 | 14.6 kT × A/cm² (2.0T) |
| Comparative Example 1-1 | 6.2 kT × A/cm² (2.7T) |
| Comparative Example 2-1 | 15.5 kT × A/cm² (2.2T) |
| Comparative Example 2-2 | 10.8 kT × A/cm² (2.4T) |
| Comparative Example 2-3 | 5.1 kT × A/cm² (2.2T) |
| Comparative Example 3-1 | 11.6 kT × A/cm² (2.4T) |
| Comparative Example 3-2 | 11.0 kT × A/cm² (2.4T) |
| Comparative Example 3-3 | 4.6 kT × A/cm² (2.6T) |

From the table 2, it can be found that nanorods have higher pinning force compared to nanoparticles and submicron particles. Thereby, it can be confirmed that nanorods can cause efficient enhancement.

From the above-mentioned experimental results, it can be confirmed that the doping of nanorods in superconductor bulks according to the present invention can improve the critical current density and magnetic trapping field compared to nanoparticles and submicron particles, and the increase tendency of critical current density and magnetic trapping field of superconductor bulks becomes more apparent with the increase of doping amount.

Although the present invention has been explained in relation to its preferred embodiment, it is to be understood that many other possible modifications and variations can be made without departing from the spirit and scope of the invention as hereinafter claimed.

What is claimed is:

1. A method for manufacturing a nanorod-containing precursor powder, comprising:
(A) providing a precursor powder; and
(B) forming a plurality of nanorods on particle surfaces of the precursor powder.

2. The method for manufacturing a nanorod-containing precursor powder as claimed in claim 1, wherein the precursor powder includes Y₂BaCuO₅ powder, Y₁Ba₂Cu₃O₇₋ₓ (0≦x≦0.5) powder or a mixture thereof.

3. The method for manufacturing a nanorod-containing precursor powder as claimed in claim 2, wherein the nanorods are zinc oxide nanorods, nickel oxide nanorods or a mixture thereof.

4. The method for manufacturing a nanorod-containing precursor powder as claimed in claim 3, wherein a reactive vapor comprising at lease one of zinc and nickel is further provided in the step (A), and a chemical vapor deposition process is performed in the step (B) to react the reactive vapor into the nanorods on the particle surfaces of the precursor powder.

5. The method for manufacturing a nanorod-containing precursor powder as claimed in claim 4, wherein the nanorods have an aspect ratio of 10 or more.

6. The method for manufacturing a nanorod-containing precursor powder as claimed in claim 4, wherein the reactive vapor is a metal vapor, and the metal vapor reacts with the reactive gas to form the nanorods on the particle surfaces of the precursor powder.

7. The method for manufacturing a nanorod-containing precursor powder as claimed in claim 6, wherein the reactive gas is provided in an input concentration of 10⁴ ppm-10⁶ ppm.

8. A nanorod-containing precursor powder, comprising:
a precursor powder; and
a plurality of nanorods formed on particle surfaces of the precursor powder.

9. The nanorod-containing precursor powder as claimed in claim 8, wherein the precursor powder includes Y₂BaCuO₅ powder, Y₁Ba₂Cu₃O₇₋ₓ (0≦x≦0.5) powder or a mixture thereof.

10. The nanorod-containing precursor powder as claimed in claim 9, wherein the nanorods are zinc oxide nanorods, nickel oxide nanorods or a mixture thereof.

11. The nanorod-containing precursor powder as claimed in claim 10, wherein the nanorods have an aspect ratio of 10 or more.

12. The nanorod-containing precursor powder as claimed in claim 10, wherein metal elements of the nanorods contained in the precursor powder are 2-5 wt % based on the weight of the precursor powder.

13. A method for manufacturing a nanorod-containing superconductor bulk, comprising:
(A) providing a first nanorod-containing precursor powder and forming the first nanorod-containing precursor powder into an embryo, wherein the first nanorod-containing precursor powder comprises a first precursor powder and a plurality of nanorods formed on particle surfaces of the first precursor powder; and
(B) performing a melt growth process to prepare a superconductor bulk.

14. The method for manufacturing a nanorod-containing superconductor bulk as claimed in claim 13, wherein in the step (A), a second precursor powder is further provided, and the second precursor powder is mixed with the first nanorod-containing precursor powder to prepare the embryo.

15. The method for manufacturing a nanorod-containing superconductor bulk as claimed in claim 14, wherein the first precursor powder and the second precursor powder individually include Y₂BaCuO₅ powder, Y₁Ba₂Cu₃O₇₋ₓ (0≦x≦0.5) powder or a mixture thereof.

16. The method for manufacturing a nanorod-containing superconductor bulk as claimed in claim 15, wherein the nanorods are zinc oxide nanorods, nickel oxide nanorods or a mixture thereof.

17. The method for manufacturing a nanorod-containing superconductor bulk as claimed in claim 16, wherein the nanorods have an aspect ratio of 10 or more.

18. The method for manufacturing a nanorod-containing superconductor bulk as claimed in claim 16, wherein metal elements of the nanorods contained in the first precursor powder are 2-5 wt % based on the weight of the first precursor powder.

19. The method for manufacturing a nanorod-containing superconductor bulk as claimed in claim 16, wherein the nanorods contained in the embryo are 0.01-0.1 wt % based on the total weight of the embryo.

20. A nanorod-containing superconductor bulk, comprising:
a single-domain bulk; and
a plurality of nanorods dispersed in the single-domain bulk.

21. The nanorod-containing superconductor bulk as claimed in claim 20, wherein the single-domain bulk is an YBCO single-domain bulk.

22. The nanorod-containing superconductor bulk as claimed in claim 21, wherein the nanorods are zinc oxide nanorods, nickel oxide nanorods or a mixture thereof.

23. The nanorod-containing superconductor bulk as claimed in claim 22, wherein the YBCO single-domain bulk includes an Y₁Ba₂Cu₃O₇₋ₓ (0≦x≦0.5) phase.

24. The nanorod-containing superconductor bulk as claimed in claim 23, wherein the YBCO single-domain bulk further includes plurality of Y₂BaCuO₅ particles dispersed in the Y₁Ba₂Cu₃O₇₋ₓ phase.

25. The nanorod-containing superconductor bulk as claimed in claim 22, wherein the nanorods contained in the superconductor bulk are 0.01-0.1 wt % based on the total weight of the superconductor bulk.
